(19) United States
(12) Patent Application Publication
(10) Pub. No.: US 2004/0164338 A1
(43) Pub. Date: Aug. 26, 2004

(54) Semiconductor device and method for fabricating the same

(76) Inventor: Haruhiko Koyama, Kanagawa (JP)

Correspondence Address: Finnegan, Henderson , Farabow,, Garrett & Dunner, L.L.P., 1300 I Street, N.W., Washington, DC, 20005-3315, US

(21) Appl. No.: 10/420,758

(22) Filed: Apr. 23, 2003

(30) Foreign Application Priority Data
Feb. 26, 2003 (JP) 2003-48812

(51) Int. Cl. H01L 27/108

(52) U.S. Cl. 257/301

(57) ABSTRACT

A semiconductor device according to an embodiment of the invention includes: a trench capacitor formed in a trench in a semiconductor substrate; a transistor for driving the trench capacitor; a semi-cylindrical semiconductor layer in an upper part of the trench constructing a part of a path electrically connecting the trench capacitor and the transistor; and a low-resistant layer buried in the semi-cylindrical semiconductor layer and having resistivity lower than that of the semi-cylindrical semiconductor layer.

### CROSS-REFERENCE TO RELATED APPLICATION

This application is based upon and claims the benefit of priority from the prior Japanese Patent Application No. 2003-048812, filed on Feb. 26, 2003; the entire contents of which are incorporated herein by reference.

### BACKGROUND OF THE INVENTION

1. Field of the Invention

The present invention relates to a semiconductor device and a method for fabricating the same and, more particularly, to a dynamic random access memory (DRAM) having a structure in which a trench capacitor and a diffusion layer of a transistor formed in the surface of a substrate are connected via a side-wall contact and a method for fabricating the same.

2. Related Background Art

A memory cell in a DRAM is constructed by a capacitor for storing charges (data) and a transistor having the role of a switch for controlling input/output of data.

As the capacity of a DRAM increases by four times every generation, the chip area of the DRAM tends to increase, so that the memory cells constructing the DRAM are requested to be further finer.

On the other hand, to make a memory cell operate stably even when the cell area is reduced, sufficient capacity has to be assured in the reduced small memory cell area. As a structure for assuring sufficient capacity in the small area, a trench capacitor is used.

In a DRAM using a trench capacitor, a trench is formed in a semiconductor substrate to a depth of about a few μm from the surface of the substrate, an insulating film for electrically isolating a diffusion layer of a transistor from a plate electrode is formed in an upper part of the trench, a capacitor is formed in a lower part of the trench, and a side-wall contact for electrically connecting the diffusion layer of the transistor and a storage node electrode is provided in an intermediate part.

FIG. 1 is across section showing the structure of a side-wall contact and its periphery in a DRAM using a conventional trench capacitor. FIG. 2 is a plan view showing the configuration of a trench capacitor cell portion in a DRAM using a conventional trench capacitor. FIG. 1 is a cross section taken along line A-A′ of FIG. 2. As shown in FIG. 2, the trench capacitor cell portion has usually a symmetrical structure. The cross section of FIG. 1 shows only the portion along the line A-A′, that is, only the left-half portion.

It is assumed that a p-type silicon substrate 101 is used as a semiconductor substrate. In the p-type silicon substrate 101, a trench 102 for forming a trench capacitor is formed. When the portion from the surface of the substrate 101 to the bottom face of the trench 102 is divided into substantially equal three parts of an upper-layer part, an intermediate-layer part, and a lower-layer part of the substrate 101, around the trench 102 from the intermediate-layer part to the lower-layer part of the substrate 101, a first n-type diffusion layer serving as a plate electrode 103 of the trench capacitor is formed. The plate electrode 103 is formed by charging arsenic glass (AsSG) as glass containing arsenic into the trench to about the intermediate-layer part of the substrate 101, diffusing the arsenic glass by heat treatment and, after that, removing the arsenic glass.

A first insulating film 104 is formed on the inner wall of the trench 102 in the portion where the plate electrode 103 is formed. Further, on the inner side of the first insulating film 104, a first n-type polysilicon layer 105 in which an impurity such as arsenic is doped is formed. The first n-type polysilicon layer 105 is buried in the trench 102 and, after that, etched back to a depth of 1.0 to 1.5 μm from the upper end of the trench 102 so as to be left in the portion where the plate electrode 103 is formed, that is, so as to be left only on the inner side of the first insulating film 104. On the inner wall of the trench 102 included in the upper-layer part of the substrate 101 except for an upper portion of the upper-layer part, a second insulating film 106 which is thicker than the first insulating film 104 is formed. On the inside of the second insulating film 106 and the inner side of the trench in the upper portion of the upper-layer part of the substrate 101, a second n-type polysilicon layer 107 in which an impurity such as arsenic is doped is buried. The second insulating film 106 is formed so that its upper end is positioned at a depth of 0.10 to 0.20 μm from the surface of the substrate 101, and the second n-type polysilicon layer 107 is formed so that its top face is positioned at a depth of 0.03 to 0.05 μm from the surface of the substrate 101. Consequently, as will be described later, the second n-type polysilicon layer 107 is directly in contact with the side wall of the trench in the upper portion of the upper-layer part of the substrate 101 and, in that portion, a side-wall contact 111 with the substrate 101 is provided.

In the upper and intermediate portions in the upper-layer part of the trench capacitor formed as described above, a portion which is out of an overlapped range with a source/drain region 114 of the transistor in the plan view of FIG. 2 is removed and the corners of the remaining portion are rounded, thereby forming the second n-type polysilicon layer 107 of a semi-cylindrical shape at an end portion of the remaining portion. Between the semi-cylindrical second n-type polysilicon layers 107 included in cells adjacent to each other, as a result of the process, a groove 108 is formed. Reference numeral 108 denotes a side face of the groove. On the top face of the trench capacitor and in the removed portion, a third insulating film 109 is formed as a device isolation region. Particularly, the third insulating film 109 is formed in the groove 108 so as to be isolated from the neighboring cell shown in FIG. 2.

Around the side wall of the trench 102 included in the upper portion of the upper-layer part of the substrate 101, that is, around the side wall of the trench in the portion where the second insulating film 106 is not formed, a second n-type diffusion layer 110 is formed by impurity diffusion from the second n-type polysilicon layer 107. A junction between the second n-type diffusion layer 110 and the second n-type polysilicon layer 107 is the side-wall contact 111 which connects the substrate 101 and the second n-type polysilicon layer 107 and electrically connects the trench capacitor and a transistor to be formed on the surface of the substrate.

On the surface of the substrate, a gate electrode 112 is formed via a gate insulating film 116 in a position apart from the trench 102. Near the surface of the substrate, a third n-type diffusion layer 113 as an active region of the transistor is formed between the gate electrode 112 and the trench 102 so as to be in contact with the second n-type diffusion layer 110 in a self aligned manner by using the gate electrode 112.

In the DRAM using the conventional trench capacitor constructed as described above, the third n-type diffusion layer 113 serving as the active region of the transistor and the second n-type polysilicon layer 107 as apart of the storage node electrode of the capacitor are electrically connected to each other via the side-wall contact 111 formed between the third insulating film 109 on the trench and the trench capacitor below the trench. More concretely, via a path constructed by the third n-type diffusion layer 113, the second n-type diffusion layer 110, the side-wall contact 111 and the second n-type polysilicon layer 107 processed in a semi-cylindrical shape, the transistor and the trench capacitor in the DRAM are electrically connected to each other.

Some of the conventional trench-type memory cells have a structure in which the resistance value of a storage node is reduced. Refer to, for example, Japanese Patent Laid-Open Publication No. H10-27885 (No. 27885/1998).

The value of resistance (hereinbelow, called “buried strap resistance”) of the whole path for electrically connecting the transistor and the trench capacitor of the DRAM is an important factor which exerts an influence on the write/read operation characteristics of the DRAM.

However, the structure of the conventional DRAM has a problem such that the value of the buried strap resistance and its variations are large.

One of main causes of variations in the buried strap resistance value is a variation in the width W of the second n-type polysilicon layer 107 processed in the semi-cylinder shape.

The width W of the second n-type polysilicon layer 107 is determined by relative positions of the trench 102 and the groove 108 and it cannot be avoided that a deviation occurs to a certain degree in the position of the trench 102, the width W, and the position of the groove 108. Therefore, the width W of the second n-type polysilicon layer 107 varies in a plurality of cells and it causes variations in the resistance of the n-type polysilicon layer 107. As a result, it is reflected as variations in the buried strap resistance values in a plurality of cells.

When the buried strap resistance value varies, the largest resistance value in the variations causes deterioration in the general performance of the DRAM. Therefore, when the variations in the buried strap resistance value increase, an adverse influence similar to a shift of the distribution of the resistance values to a higher direction is exerted and it causes deterioration in the operation characteristics of the DRAM.

### SUMMARY OF THE INVENTION

A semiconductor device according to an embodiment of the invention includes: a trench capacitor formed in a trench in a semiconductor substrate; a transistor for driving the trench capacitor; a semi-cylindrical semiconductor layer in an upper part of the trench constructing a part of a path electrically connecting the trench capacitor and the transistor; and a low-resistant layer buried in the semi-cylindrical semiconductor layer and having resistivity lower than that of the semi-cylindrical semiconductor layer.

A method for fabricating a semiconductor device according to an embodiment of the invention burying a low-resistant layer having resistivity lower than that of a semi-cylindrical semiconductor layer in the semi-cylindrical semiconductor layer in an upper part of a trench constructing a part of a path electrically connecting a trench capacitor formed in the trench in a semiconductor substrate and a transistor for driving the trench capacitor.

### BRIEF DESCRIPTION OF THE DRAWINGS

FIG. 1 is a cross section showing the structure of a side-wall contact and its periphery in a DRAM using a conventional trench capacitor.

FIG. 2 is a plan view showing the configuration of a trench capacitor cell portion in a DRAM using a conventional trench capacitor.

FIG. 3 is across section showing the structure of a side-wall contact and its periphery in a trench capacitor in a semiconductor device according to an embodiment of the invention.

FIG. 4 is a plan view showing the configuration of a trench capacitor cell portion in the semiconductor device according to the embodiment of the invention.

FIGS. 5A to 5F are cross sections each showing the structure of a side-wall contact and its periphery of a trench capacitor in a step of a method for fabricating a semiconductor device according to an embodiment of the invention.

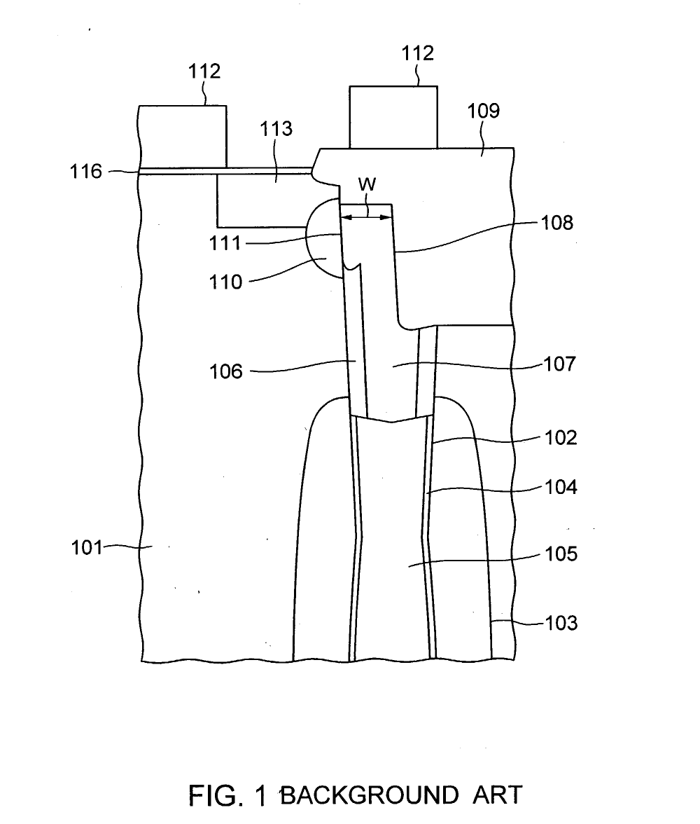

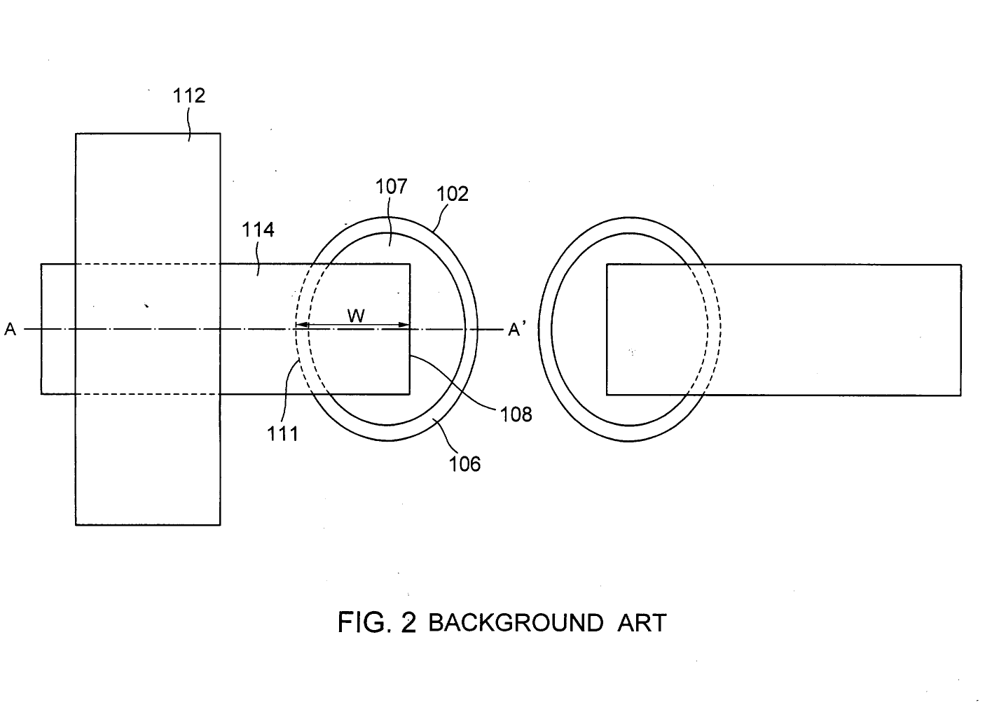

### DETAILED DESCRIPTION OF THE EMBODIMENTS

A semiconductor device and a method for fabricating the same according to an embodiment of the invention will be described hereinbelow with reference to the drawings.

In a semiconductor device and a method for fabricating the same according to an embodiment of the invention, in a semiconductor layer of a semi-cylindrical shape in an upper portion of a trench as a part of a path which electrically connects a trench capacitor and a diffusion layer of a transistor formed on the surface of a substrate in a semiconductor device using the trench capacitor, another material of which resistivity is lower than that of the semi-cylindrical semiconductor layer is buried. With the configuration, resistance in the path electrically connecting the trench capacitor and the diffusion layer of the transistor and its variations are reduced.

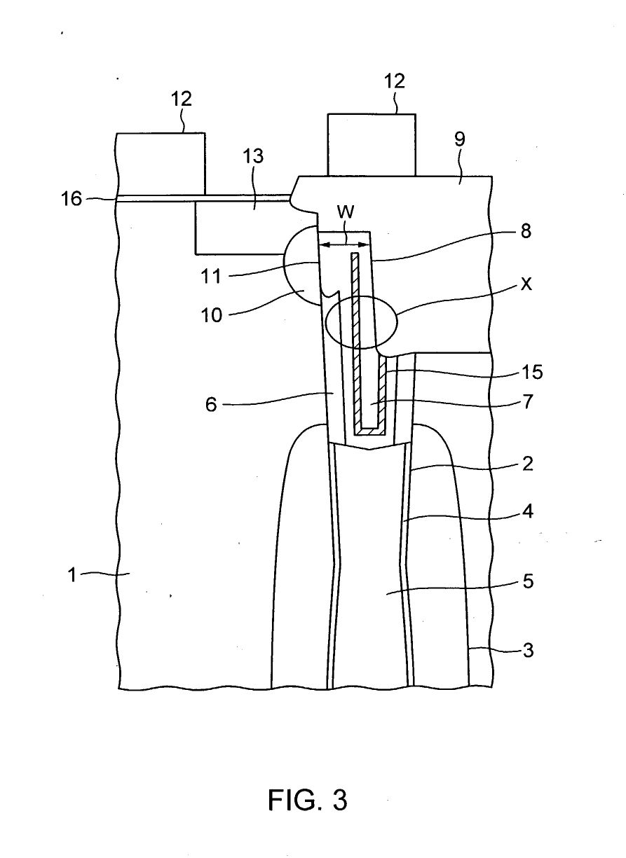

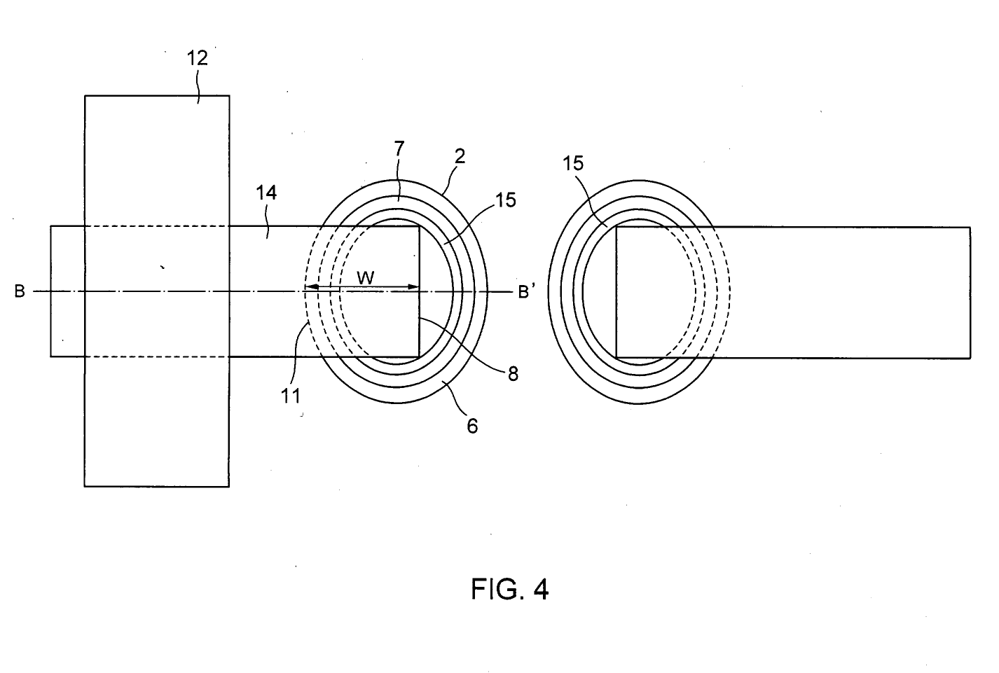

FIG. 3 is across section showing the structure of a side-wall contact in a trench capacitor and its periphery in a semiconductor device according to an embodiment of the invention. FIG. 4 is a plan view showing the configuration of a trench capacitor cell portion in the semiconductor device according to the embodiment of the invention. FIG. 3 is a cross section taken along line B-B′ of FIG. 4. As shown in FIG. 4, the trench capacitor cell portion is usually symmetrical. FIG. 3 shows only the portion taken along B-B′ line, that is, only the left-half portion.

It is assumed that a p-type silicon substrate (semiconductor substrate) 1 is used. In the p-type silicon substrate 1, a trench 2 for forming a trench capacitor is formed. When the portion from the surface of the substrate 1 to the bottom face of the trench 2 is divided into substantially equal three parts of an upper-layer part, an intermediate-layer part, and a lower-layer part, around the trench 2 in the intermediate-layer part and the lower-layer part of the substrate 1, a first n-type diffusion layer serving as a plate electrode 3 of the trench capacitor is formed. The plate electrode 3 is formed by charging arsenic glass (AsSG) as glass containing arsenic to about the intermediate-layer part of the substrate 1, diffusing the arsenic included in the arsenic glass by heat treatment and, after that, removing the arsenic glass.

A first insulating film 4 is formed on the inner wall of the trench 2 in the portion where the plate electrode 3 is formed. Further, on the inner side of the first insulating film 4, a first n-type polysilicon layer 5 in which an impurity such as arsenic is doped is buried. The first n-type polysilicon layer 5 is buried in the trench 2 and, after that, etched back to a depth of about 1.0 to 1.5 m from the upper end of the trench 2 so as to be left in the portion where the plate electrode 3 is formed, that is, so as to be left only on the inner side of the first insulating film 4. On the inner wall of the trench 2 included in the upper-layer part of the substrate 1 except for an upper portion of the upper-layer part of the substrate 1, a second insulating film 6 which is thicker than the first insulating film 4 is formed. On the inside of the second insulating film 6 and the inner side of the trench in the upper portion of the upper-layer part of the substrate 1, a second n-type polysilicon layer 7 in which an impurity such as arsenic is doped is buried. The second insulating film 6 is formed so that its upper end is positioned at a depth of about 0.1 to 0.2 μm from the surface of the substrate 1, and the second n-type polysilicon layer 7 is formed so that its top face is positioned at a depth of about 0.03 to 0.05 μm from the surface of the substrate 1. Consequently, as will be described later, the second n-type polysilicon layer 7 is directly in contact with the side wall of the trench in the upper portion of the upper-layer part of the substrate 1 and, in that portion, a side-wall contact 11 with the substrate 1 is provided.

Moreover, in the semiconductor device according to the embodiment of the invention, a low-resistant film 15 of a form serving as a part of a cylindrical film made of a material of which resistivity is lower than that of the second n-type polysilicon layer 7 is sandwiched in the second n-type polysilicon layer 7. A concrete method of forming the low-resistant film 15 will be described in detail later. Briefly, the material of the second n-type polysilicon layer 7 is deposited, the low-resistant film 15 is formed on the inner wall of the second n-type polysilicon layer 7, and the material of the second n-type polysilicon layer 7 is further deposited so as to bury the low-resistant film 15, thereby sandwiching the cylindrical-shape low-resistant film 15 by the second n-type polysilicon layer 7. Normally, a part of the cylindrical low-resistant film 15 is removed in a process of processing the second n-type polysilicon layer 7, so that the low-resistant film 15 serves as a part of the cylindrical film. The shape of the low-resistant film 15 is not limited to a form of a cylindrical film or a part of the cylindrical film but is arbitrary. The second n-type polysilicon layer 7 and the low-resistant film 15 construct a part of the storage node electrode of the trench capacitor.

In the upper and intermediate portions in the upper-layer portion of the trench capacitor formed as described above, a portion which is out of an overlapped range with a source/drain region 14 of the transistor in the plan view of FIG. 4 is removed and the corners of the remaining portion are rounded, thereby forming the second n-type polysilicon layer 7 of a semi-cylindrical shape at an end portion of the remaining portion. Between the semi-cylindrical second n-type polysilicon layers 7 included in cells adjacent to each other, as a result of the process, a groove 8 is formed. Reference numeral 8 denotes a side face of the groove. On the top face of the trench capacitor and in the removed portion, a third insulating film 9 is formed as a device isolation region. Particularly, the third insulating film 9 is formed in the groove 8 so as to be isolated from the neighboring cells shown in FIG. 4.

Around the side wall of the trench 2 included in the upper portion of the upper-layer part of the substrate 1, that is, around the side wall of the trench in the portion where the second insulating film 6 is not formed, a second n-type diffusion layer 10 is formed by impurity diffusion from the second n-type polysilicon layer 7. A junction between the second n-type diffusion layer 10 and the second n-type polysilicon layer 7 is the side-wall contact 11 which connects the substrate 1 and the second n-type polysilicon layer 7 and electrically connects the trench capacitor and a transistor to be formed on the surface of the substrate.

On the surface of the substrate, a gate electrode 12 is formed via a gate insulating film 16 in a position apart from the trench 2. Near the surface of the substrate, a third n-type diffusion layer 13 as an active region of the transistor is formed between the gate electrode 12 and the trench 2 so as to be in contact with the second n-type diffusion layer 10 in a self aligned manner by using the gate electrode 12. The transistor in the embodiment is an MOS transistor.

In the semiconductor device according to the embodiment of the invention constructed as described above, in the semi-cylindrical semiconductor layer 7 in the upper-layer part of the trench, serving as a part of the path connecting the trench capacitor in the semiconductor device such as a DRAM using the trench capacitor and the diffusion layer 13 of the transistor formed in the surface of the substrate, the low-resistant film 15 having resistivity lower than that of the semi-cylindrical semiconductor layer 7 is buried. Consequently, when current passes through the semi-cylindrical semiconductor layer 7 in the upper-layer part of the trench and flows between the diffusion layer 13 of the transistor and the trench capacitor, the current selectively flows in the low-resistant layer 15 in the semi-cylindrical semiconductor layer 7.

For example, the width of a portion X as a part of the current path in the semi-cylindrical semiconductor layer 7 depends on the width W of the semi-cylindrical semiconductor layer 7, and the width W of the semi-cylindrical semiconductor layer 7 depends on a deviation in matching in manufacture with respect to the relative positions of the trench 2 and the groove 8 and there are some variations in a plurality of cells. Consequently, the resistance value of the semi-cylindrical semiconductor layer 7 also varies among a plurality of cells.

However, in the semiconductor device according to the embodiment of the invention, the low-resistant film 15 is buried so as to be sandwiched in the semi-cylindrical semiconductor layer 7. Even if the deviation in manufacture with respect to the relative positions of the trench 2 and the groove 8 occurs, variations in a removal amount of the low-resistant film 15 in association with formation of the groove 8 are small.

Therefore, the resistance value in the case where the current flowing in the semi-cylindrical semiconductor layer 7 selectively flows in the low-resistant film 15 hardly vary among a plurality of cells. Thus, variations in the resistance value (strap resistance value) of the path electrically connecting the trench capacitor and the diffusion layer can be reduced. Further, by burying the low-resistant film 15 in the semi-cylinder semiconductor layer 7, the strap resistance value itself can be also reduced. As a result, in the semiconductor device such as a DRAM, in the case of employing the above-described configuration, the general performance of the device can be improved.

A method for fabricating the semiconductor device according to the embodiment of the invention will now be described.

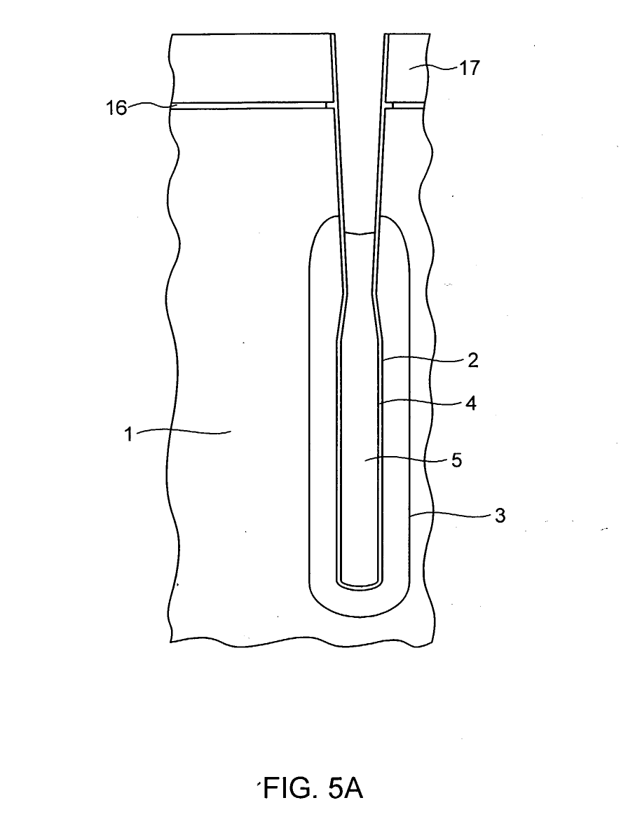

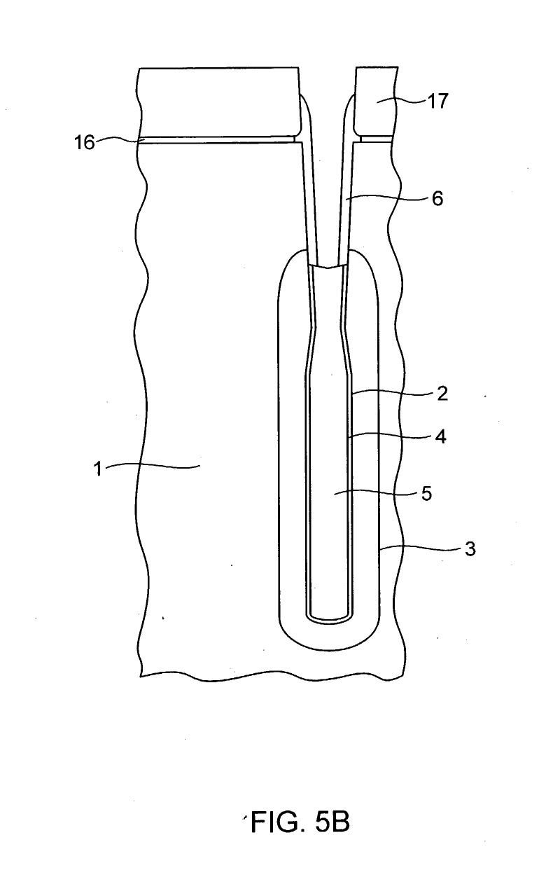

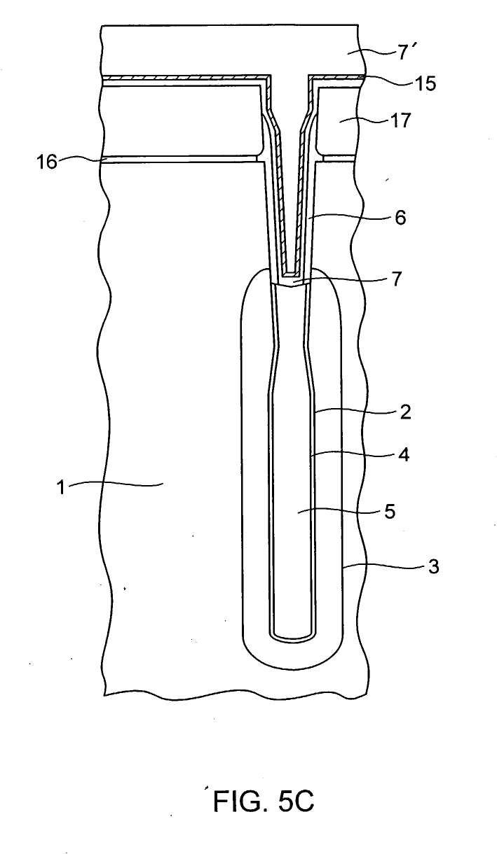

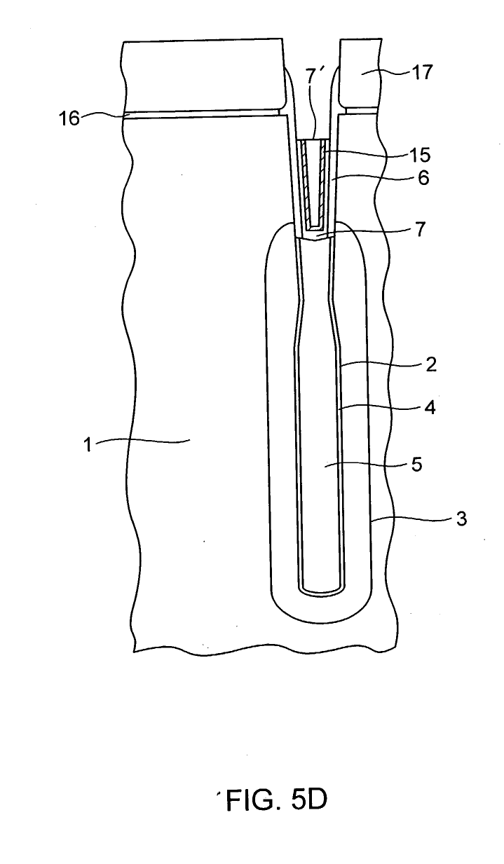

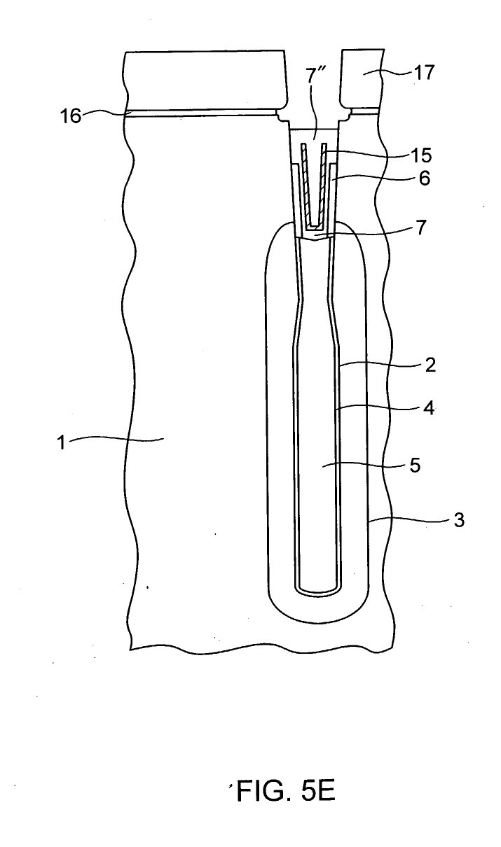

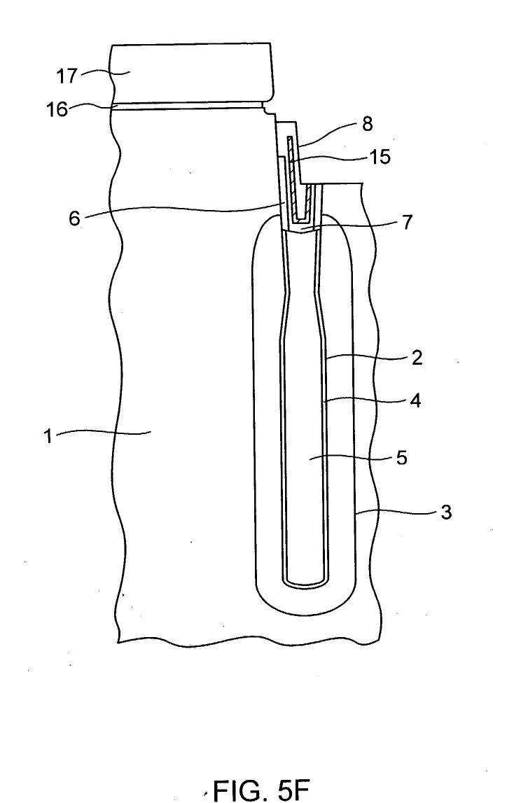

FIGS. 5A to 5F are cross sections each showing the structure of a side-wall contact and its periphery of a trench capacitor in a step of the method for fabricating the semiconductor device according to the embodiment of the invention.

First, as shown in FIG. 5A, by using a silicon nitride film (SiN) 17 as a masking member formed on the p-type silicon substrate 1 via the gate insulating film 16, a silicon oxide film (SiO₂) formed on the silicon nitride film 17 or the like as a mask, the trench 2 having a depth of about 8 μm from the surface of the substrate land a diameter of about 0.2 μm is formed. The diameter of the trench is set to, for example, about 210 nm. After formation of the trench 2, arsenic glass (AsSG) as a glass containing arsenic is deposited in the trench 2 up to about the intermediate-layer part of the substrate 1 and diffused by heat treatment, thereby forming the first n-type diffusion layer 3 around the trench in a range from the intermediate-layer part to the lower-layer part of the trench and using it as the plate electrode 3 of the trench capacitor. After formation of the plate electrode 3, arsenic glass in the trench 2 is removed. After that, the first insulating film 4 having a thickness of about 5 nm is formed on the inner wall of the trench 2. As the first insulating film 4, a silicon nitride film (SiN) is often used. The thickness of the first insulating film 4 is, for example, about 5 to 6 nm. After formation of the first insulating film 4, the first n-type polysilicon layer 5 in which an impurity such as arsenic (As) is doped at high concentration to achieve low resistance is formed and buried in the trench. The first n-type polysilicon layer 5 is etched back by anisotropic or isotropic etching so that the first n-type polysilicon layer 5 remains only in the trench 2 in the portion in which the plate electrode 3 is formed.

After processing the first n-type polysilicon layer 5, the second insulating film 6 is deposited and, as shown in FIG. 5B, anisotropic etching is performed so that the second insulating film 6 remains only on the inner wall of the trench 2. As the second insulating film 6, a silicon oxide film (SiO₂) is often used. The thickness of the second insulating film 6 is, for example, about 30 nm.

After processing the second insulating film 6, as shown in FIG. 5C, the second n-type polysilicon layer 7 in which an impurity such as arsenic (As) is doped at high concentration is formed to a degree at which the trench 2 is not buried, and the low-resistant film 15 having resistivity lower than that of the second n-type polysilicon layer 7 is deposited. The second n-type polysilicon layer 7 is formed as thin as possible. The thickness is set to, for example, about 30 nm. As the material of the low-resistant film 15, a refractory metal such as tungsten silicide or molybdenum silicide is used. The thickness of the low-resistant film 15 is, for example, about 10 to 20 nm. After that, an additional second n-type polysilicon layer 7′ in which an impurity such as arsenic is doped at high concentration is formed to completely bury the trench 2. The same material may be used for the second n-type polysilicon layer 7 and the additional second n-type polysilicon layer 7′. Further, the same material as that of the first n-type polysilicon layer 5 maybe used for the second n-type polysilicon layer 7 and the additional second n-type polysilicon layer 7′.

After the trench 2 is buried with the additional second n-type polysilicon layer 7′, as shown in FIG. 5D, the second n-type polysilicon layer 7, additional second n-type polysilicon layer 7′ and low-resistant film 15 are etched by anisotropic or isotropic dry etching so that the surface of each of the layers in the trench 2 is positioned at a depth of about 0.1 μm from the surface of the substrate 1.

After etching the second n-type polysilicon layer 7, additional second n-type polysilicon layer 7′ and low-resistant film 15, the upper portion of the second insulating film 6 is removed by wet etching using ammonium fluoride (NH₄F) or the like so that the upper end of the second insulating film 6 is positioned at a depth of about 0.1 to 0.2 μm from the surface of the substrate. After processing the second insulating film 6, another additional second n-type polysilicon layer 7″ is formed to completely bury the trench again. After that, as shown in FIG. 5E, the another additional second n-type polysilicon layer 7″ is etched by anisotropic or isotropic dry etching so that the surface of the another additional second n-type polysilicon layer 7″ in the trench 2 is positioned at a depth of about 0.03 to 0.05 μm from the surface of the substrate 1.

The second n-type polysilicon layer 7, additional second n-type polysilicon layer 7′, and another additional second-n-type polysilicon layer 7″ are integrally formed as a result of the processes and have similar functions. Consequently, the layers will be generically called the second n-type polysilicon layer 7 hereinbelow.

After the process shown in FIG. 5E, by using the resist formed by lithography as a mask, the groove 8 is formed by anisotropic dry etching as shown in FIG. 5F. Alternately, after the process shown in FIG. 5E, an oxide film or the like is deposited, the surface is planarized and, after that, the groove 8 is formed by lithography and dry etching. After that, the groove 8 is filled with the insulating film (the third insulating film 9 in FIG. 3, which is not shown in FIG. 5F), the surface is planarized by CMP, and the silicon nitride film 17 formed as a mask material is removed. As described above, the groove 8 and the insulating film are to isolate from the adjacent cell on the right side in FIG. 5F.

After formation of the device isolation region, the gate electrode 12, the third n-type diffusion layer 13 as an active region, and the like as components of the transistor are formed by normal processes. In such a manner, the structure of the side-wall contact of the trench capacitor and its periphery in the semiconductor device according to the embodiment of the invention shown in FIGS. 3 and 4 is obtained.

In the semiconductor device according to the embodiment of the invention and the method for fabricating the same, in a semi-cylindrical semiconductor layer in an upper part of a trench as a part of a path electrically connecting a trench capacitor formed in the trench in a semiconductor substrate and a transistor for driving the trench capacitor, a low-resistant layer having resistivity lower than that of the semi-cylindrical semiconductor layer is buried. With the configuration, variations in the resistance value (strap resistance value) of the path electrically connecting the trench capacitor and the diffusion layer can be reduced and the strap resistance value itself can be also reduced. As a result, in a semiconductor device such as a DRAM, the general performance of the device can be improved.

What is claimed is:

1. A semiconductor device comprising:
a trench capacitor formed in a trench in a semiconductor substrate;
a transistor for driving said trench capacitor;
a semi-cylindrical semiconductor layer in an upper part of said trench constructing a part of a path electrically connecting said trench capacitor and said transistor; and
a low-resistant layer buried in said semi-cylindrical semiconductor layer and having resistivity lower than that of said semi-cylindrical semiconductor layer.

2. The semiconductor device according to claim 1, wherein said low-resistant layer is buried so as to be sandwiched by said semi-cylindrical semiconductor layer in the form of a part of a cylindrical film.

3. The semiconductor device according to claim 1, wherein said low-resistant layer is made of a refractory metal.

4. The semiconductor device according to claim 3, wherein said refractory metal is tungsten silicide.

5. The semiconductor device according to claim 3, wherein said refractory metal is molybdenum silicide.

6. The semiconductor device according to claim 1, wherein a part of said semi-cylinder semiconductor layer serves as a side-wall contact with said semiconductor substrate, which is in direct contact with a side wall of said trench.

7. The semiconductor device according to claim 1, wherein said low-resistant layer and said semi-cylindrical semiconductor layer construct a part of a storage node electrode of said trench capacitor.

8. The semiconductor device according to claim 1, wherein said transistor is a MOS transistor.

9. A method for fabricating a semiconductor device burying a low-resistant layer having resistivity lower than that of a semi-cylindrical semiconductor layer in the semi-cylindrical semiconductor layer in an upper part of a trench constructing a part of a path electrically connecting a trench capacitor formed in said trench in a semiconductor substrate and a transistor for driving said trench capacitor.

10. The method for fabricating a semiconductor device according to claim 9, wherein said low-resistant layer is buried so as to be sandwiched by said semi-cylindrical semiconductor layer in the form of a part of a cylindrical film.

11. The method for fabricating a semiconductor device according to claim 9, wherein said low-resistant layer is made of a refractory metal.

12. The method for fabricating a semiconductor device according to claim 11, wherein said refractory metal is tungsten silicide.

13. The method for fabricating a semiconductor device according to claim 11, wherein said refractory metal is molybdenum silicide.

14. The method for fabricating a semiconductor device according to claim 9, wherein a part of said semi-cylinder semiconductor layer serves as a side-wall contact with said semiconductor substrate, which is in direct contact with a side wall of said trench.

15. The method for fabricating a semiconductor device according to claim 9, wherein said low-resistant layer and said semi-cylindrical semiconductor layer construct apart of a storage node electrode of said trench capacitor.

16. The method for fabricating a semiconductor device according to claim 9, wherein said transistor is a MOS transistor.
